(19) United States
(12) Patent Application Publication
(10) Pub. No.: US 2010/0065930 A1
(43) Pub. Date: Mar. 18, 2010

(54) Method of etching sacrificial layer, method of manufacturing MEMS device, MEMS device and MEMS sensor

(75) Inventor: Goro Nakatani, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/585,552

(22) Filed: Sep. 17, 2009

(30) Foreign Application Priority Data
Sep. 18, 2008 (JP) 2008-239552
Sep. 25, 2008 (JP) 2008-245863

(51) Int. Cl. H01L 29/84; H01L 21/306; H01L 29/06

(52) U.S. Cl. 257/415; 438/694; 257/629; 257/E21.215; 257/E29.005; 257/E29.324

(57) ABSTRACT

The method of etching a sacrificial layer according to the present invention includes the steps of forming a sacrificial layer having a protrusive shape on a base layer, forming a covering film covering the sacrificial layer, forming a protective film made of a material whose etching selection ratio to the sacrificial layer is greater than the etching selection ratio of the covering film to the sacrificial layer on a portion of the covering film opposed to the side surface of the sacrificial layer, and etching the sacrificial layer after the formation of the protective film.

### BACKGROUND OF THE INVENTION

1. Field of the Invention

The present invention relates to a method of etching a sacrificial layer, a method of manufacturing an MEMS device with the etching method and an MEMS device manufactured according to the manufacturing method, as well as an MEMS sensor.

2. Description of Related Art

A device to which an MEMS (Micro Electro Mechanical Systems) technique is applied has been recently loaded on a portable telephone or the like, and hence an MEMS device is increasingly watched with interest. For example, a silicon microphone is known as a typical MEMS device.

FIGS. 6A to 6I are schematic sectional views showing a method of manufacturing a conventional silicon microphone in step order.

In order to manufacture the conventional silicon microphone, a thermal oxide film 111 and a thermal oxide film 121 are first formed on a first surface and a second surface of a silicon substrate 102 by thermal oxidation, as shown in FIG. 6A.

Then, a plurality of recesses 112 are formed in the thermal oxide film 111 by etching the thermal oxide film 111 from a first side, as shown in FIG. 6B.

Then, polysilicon is deposited by LPCVD (Low Pressure Chemical Vapor Deposition), to cover the overall regions of the surfaces of the thermal oxide films 111 and 121. The polysilicon covering the thermal oxide film 111 is doped with an impurity, and portions of the polysilicon other than prescribed portions including those entering the recesses 112 are thereafter removed. Thus, a diaphragm 104 having protrusions 108 entering the recesses 112 thereby protruding toward the silicon substrate 102 is formed on the thermal oxide film 111, as shown in FIG. 6C. On the other hand, a polysilicon film 113 consisting of the deposited polysilicon is formed on the thermal oxide film 121, as shown in FIG. 6C.

Then, silicon oxide is deposited on a first side of the silicon substrate 102 by PECVD (Plasma Enhanced Chemical Vapor Deposition), to cover the diaphragm 104. Then, unnecessary portions of the silicon oxide are removed by etching. Thus, a sacrificial oxide film 114 covering the diaphragm 104 and a second insulating film 119 surrounding the diaphragm 104 are formed, as shown in FIG. 6D.

Then, polysilicon is deposited on the first side and a second side of the silicon substrate 102 by LPCVD. The polysilicon deposited on the first side of the silicon substrate 102 is doped with an impurity, and thereafter patterned. Thus, a back plate 105 having a large number of holes 106 is formed on the sacrificial oxide film 114 on the first side of the silicon substrate 102, as shown in FIG. 6E. On the second side of the silicon substrate 102, on other hand, the deposited polysilicon and the polysilicon film 113 are integrated into a polysilicon film 115, as shown in FIG. 6E.

Then, a plurality of recesses 117 are formed in the sacrificial oxide film 114 by etching the sacrificial oxide film 114 through the holes 106, as shown in FIG. 6F. Then, portions of the thermal oxide film 111 exposed from the sacrificial oxide film 114 and the second insulating film 119 are removed, as shown in FIG. 6F. Thus, a sacrificial oxide film 122 is formed by the portion of thermal oxide film 111 remaining between the sacrificial oxide film 114 and the silicon substrate 102 and the sacrificial oxide film 114. Further, a first insulating film 123 is formed by the portion of the thermal oxide film 111 remaining between the second insulating film 119 and the silicon substrate 102.

Then, silicon nitride is deposited on the first side of the silicon substrate 102 by PECVD to cover the overall regions of the surfaces of the sacrificial oxide film 122 and the second insulating film 119, as shown in FIG. 6G. Thus, a surface film 107 having a plurality of protrusions 109 entering the recesses 117 of the sacrificial oxide film 114 thereby protruding toward the silicon substrate 102 is formed.

Then, portions of the surface film 107 opposed to the holes 106 are etched, as shown in FIG. 6H. Thus, holes 118 communicating with the holes 106 of the back plate 105 are formed in the surface film 107.

On the other hand, an opening 120 is formed in the thermal oxide film 121 by etching a portion of the thermal oxide film 121 opposed to the diaphragm 104, as shown in FIG. 6H.

Then, the silicon substrate 102 is dipped in a vessel filled up with an etching solution containing hydrofluoric acid, for example. Thus, the etching solution is supplied to the second surface of the silicon substrate 102 through the opening 120, to etch the silicon substrate 102. Further, the etching solution is supplied to the sacrificial oxide film 122 through the holes 116 and 118, to remove the sacrificial oxide film 122.

Thus, a sound hole 103 passing through the silicon substrate 102 from the second surface toward the first surface is formed in the silicon substrate 102, as shown in FIG. 6I. The diaphragm 104 floats up from the first surface of the silicon substrate 102, while a gap 110 of a small interval is formed between the diaphragm 104 and the back plate 105. The diaphragm 104 is cantilever-supported by the first insulating film 123 and the second insulating film 119 on an unshown position. The surface film 107 having covered the surface of the sacrificial oxide film 122 forms a hollow supporting film supported in a state having a hollow portion between the same and the first surface of the silicon substrate 102, due to the removal of the sacrificial oxide film 122.

Thereafter a silicon microphone 101 is obtained by dividing the silicon substrate 102 into the size of each device.

In the silicon microphone 101, the diaphragm 104 and the back plate 105 constitute a capacitor having the diaphragm 104 and the back plate 105 as counter electrodes. A prescribed voltage is applied to the capacitor (between the diaphragm 104 and the back plate 105).

When a sound pressure (a sound wave) is input from the sound hole 103 in this state, the diaphragm 104 vibrates due to the action of the sound pressure to change the capacitance of the capacitor, and voltage fluctuation between the diaphragm 104 and the back plate 105 resulting from the change of the capacitance is output as a sound signal.

The hollow structure of the surface film 107 of the silicon microphone 101 is formed through a high etching selection ratio between the silicon oxide employed as the material for the sacrificial oxide film 122 and the silicon nitride employed as the material for the surface film 107.

However, the etching selection ratio between the silicon oxide and the silicon nitride is not infinite. When the sacrificial oxide film 122 is etched, therefore, the surface film 107 exposed to the etching solution is slightly etched. A portion of the surface film 107 opposed to the side surface of the sacrificial oxide film 122 is insufficient in coverage as compared with the remaining portions of the surface film 107, and hence the portion may be remarkably eroded by the etching solution and damaged by the etching.

In the silicon microphone 101, further, the conductive diaphragm 104 is exposed in the gap 110. When the diaphragm 104 is attracted to the backplate 105 by electrostatic force or the like, therefore, the diaphragm 104 and the back plate 105 may come into contact with each other, to cause a short circuit therebetween.

In the silicon microphone 101, therefore, the surface film 107 is partially introduced into the holes 106 of the back plate 105, thereby forming the protrusions 109 whose forward ends protrude to be positioned closer to the silicon substrate 102 than the lower surface of the back plate 105. Thus, the protrusions 109 come into contact with the diaphragm 104 before the diaphragm 104 and the back plate 105 are brought into contact with each other, thereby preventing the diaphragm 104 and the back plate 105 from coming into contact with each other.

In order to form the protrusions 109, however, the recesses 117 for partially receiving the surface film 107 must be formed by patterning the portions of the sacrificial oxide film 114 exposed in the holes 106 of the back plate 105 in a fine pattern (see FIG. 6F). The manufacturing steps for the silicon microphone 101 are disadvantageously complicated due to the unavoidable addition of the fine etching step.

On the other hand, the diaphragm 104 and the back plate 105 may conceivably be prevented from coming into contact with each other by supplying the diaphragm 104 with large tension thereby reducing the vibrational amplitude of the diaphragm 104. When supplied with large tension, however, the sensitivity of the silicon microphone 101 is reduced due to difficulty in vibration of the diaphragm 104.

### SUMMARY OF THE INVENTION

An object of the present invention is to provide a method of etching a sacrificial layer capable of suppressing damage of a covering film induced by the etching when the sacrificial layer covered with the covering film is etched.

Another object of the present invention is to provide a method of manufacturing an MEMS device, having a hollow supporting film formed by forming a covering film covering a sacrificial layer and etching the sacrificial layer, capable of suppressing damage of the hollow supporting film induced by the etching and an MEMS device manufactured by the method.

Still another object of the present invention is to provide an MEMS sensor capable of preventing a short circuit resulting from contact between a vibrating film such as a diaphragm and a counter electrode such as a back plate with a simple structure while ensuring vibratility of the vibrating film.

The foregoing and other objects, features and effects of the present invention will become more apparent from the following detailed description of the embodiments with reference to the attached drawings.

### BRIEF DESCRIPTION OF THE DRAWINGS

FIG. 1 is a schematic sectional view of a silicon microphone according to a first embodiment of the present invention.

FIGS. 2A to 2J are schematic sectional views showing a method of manufacturing the silicon microphone shown in FIG. 1 in step order.

FIG. 3 is a schematic sectional view of a silicon microphone according to a second embodiment of the present invention.

FIG. 4 is a schematic plan view of a diaphragm shown in FIG. 3.

FIGS. 5A to 5N are schematic sectional views showing a method of manufacturing the silicon microphone shown in FIG. 3 in step order.

FIGS. 6A to 6I are schematic sectional views showing a method of manufacturing a conventional silicon microphone in step order.

### DETAILED DESCRIPTION OF PREFERRED EMBODIMENTS

A method of etching a sacrificial layer according to one embodiment of the present invention includes the steps of forming a sacrificial layer having a protrusive shape on a base layer, forming a covering film covering the sacrificial layer, forming a protective film made of a material whose etching selection ratio to the sacrificial layer is greater than the etching selection ratio of the covering film to the sacrificial layer on a portion of the covering film opposed to the side surface of the sacrificial layer, and etching the sacrificial layer after the formation of the protective film.

According to the method, the protective film made of the material whose etching selection ratio to the sacrificial layer is greater than the etching selection ratio of the covering film to the sacrificial layer is formed on the portion (a side portion of the covering film) of the covering film opposed to the side surface of the sacrificial layer, in advance of the etching of the sacrificial layer. In other words, the protective film having a smaller quantity of etching (a smaller quantity of erosion) by an etching solution for removing the sacrificial layer than the covering film is formed on the side portion of the covering film.

When the sacrificial layer is etched, therefore, the quantity of erosion by the etching solution can be reduced on the side portion of the covering film. Consequently, damage of the covering film induced by the etching can be suppressed.

The method of etching a sacrificial layer is employed for a method of manufacturing an MEMS device according to one embodiment of the present invention, for example. In other words, the method of manufacturing an MEMS device according to one embodiment of the present invention includes the steps of forming a sacrificial layer having a protrusive shape on a surface of a substrate, forming a covering film covering the sacrificial layer, forming a protective film made of a material whose etching selection ratio to the sacrificial layer is greater than the etching selection ratio of the covering film to the sacrificial layer on a portion of the covering film opposed to the side surface of the sacrificial layer, and working the covering film into a hollow supporting film supported in a state having a hollow portion between the same and the surface of the substrate by removing the sacrificial layer by etching thereby forming a space between the covering film and the substrate.

According to the method, as hereinabove described, the quantity of erosion by the etching solution can be reduced on the side portion of the covering film when the sacrificial layer is etched. Consequently, damage of the hollow supporting film formed by removing the sacrificial layer by etching can be suppressed.

An MEMS device according to one embodiment of the present invention can be manufactured by the method of manufacturing an MEMS device. In other words, an MEMS device including a substrate, a hollow supporting film, integrally having an opposed portion opposed to a surface of the substrate at an interval, a step portion formed on the surface of the substrate and a side portion connecting the opposed portion and the step portion with each other, supported in a state having a hollow portion between the same and the surface of the substrate, and a protective film selectively formed on the side portion of the hollow supporting film can be manufactured by the method of manufacturing an MEMS device according to one embodiment of the present invention.

In the aforementioned method of etching a sacrificial layer, the step of forming the protective film preferably includes the steps of depositing the material for the protective film on the overall surface of the covering film, and leaving the material on a portion of the covering film opposed to the side surface of the sacrificial layer by etching back the deposited material.

Damage of the covering film induced by etching may conceivably be suppressed by a technique of presuming the quantity of erosion of the covering film by the etching and uniformly increasing the thickness of the covering film on the basis of the presumed quantity of erosion, for example. In order to form a covering film having a large thickness, however, the time for forming the covering film must be increased. Therefore, if the technique is employed for the method (excluding the step of forming the protective film) of manufacturing an MEMS device according to one embodiment of the present invention, for example, the time for manufacturing the MEMS device is increased as a whole, and the production efficiency is reduced.

According to the method of etching a sacrificial layer of the aforementioned aspect, on the other hand, the protective film is formed by depositing the material for the protective film on the overall surface of the covering film and etching back the deposited material. In other words, the protective film is prepared by the simple technique of depositing the protective film material and etching back the deposited protective film material. Therefore, increase in the manufacturing time can be suppressed in the method of manufacturing an MEMS device employing the technique. Consequently, damage of the covering film (the hollow supporting film) induced by the etching can be suppressed without reducing the production efficiency for the MEMS device.

An MEMS sensor according to one embodiment of the present invention includes a substrate, a vibrating film opposed to the substrate at an interval on a side of the substrate and vibratile in the opposed direction, and a counter electrode, made of a conductive material, opposed to the vibrating film at an interval on a side of the vibrating film opposite to the substrate, while the vibrating film includes a metal electrode and a resin material film covering the metal electrode.

According to the structure, the vibrating film having the metal electrode and the counter electrode made of the conductive material are opposed to each other at an interval, thereby constituting a capacitor having the vibrating film and the counter electrode as counter electrodes. In the vibrating film serving as one of the counter electrodes, the metal electrode which is a conductive portion is covered with the resin material film.

Even if the vibrating film and the counter electrode come into contact with each other, therefore, the resin material film forming the surface of the vibrating film inhibits the metal electrode from coming into contact with the counter electrode. Consequently, a short circuit resulting from contact between the vibrating film and the counter electrode can be prevented. Further, the vibrating film and/or the counter electrode may not be provided with protrusions protruding in the opposed direction thereof, whereby complication of the manufacturing steps can also be suppressed.

When the metal electrode is covered with the resin material film, on the other hand, the vibrating film more easily vibrates as compared with a vibrating film made of only a metallic material and formed to have the same thickness as the vibrating film. Therefore, a short circuit resulting from contact between the vibrating film and the counter electrode can be prevented while ensuring vibratility of the vibrating film.

The metal electrode is covered with the resin material film, whereby corrosion (deterioration) of the metal electrode resulting from natural oxidation or the like can also be suppressed.

The vibrating film preferably has a main portion on which the metal electrode is arranged and supporting portions extending from a plurality of positions of the peripheral edge of the main portion in directions along the surface of the substrate.

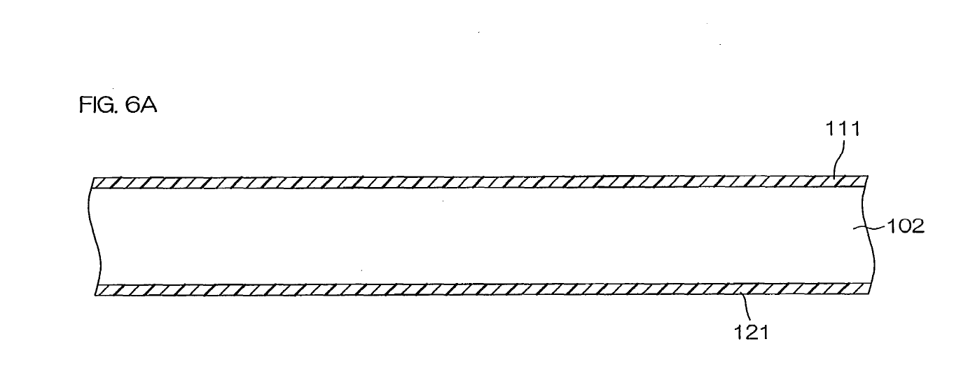

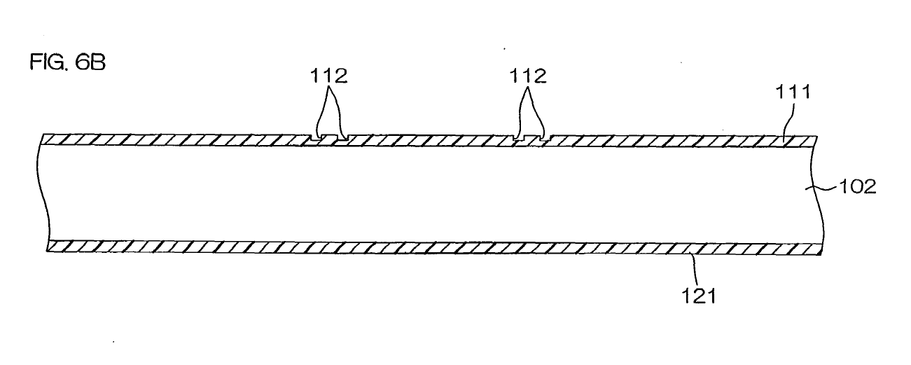

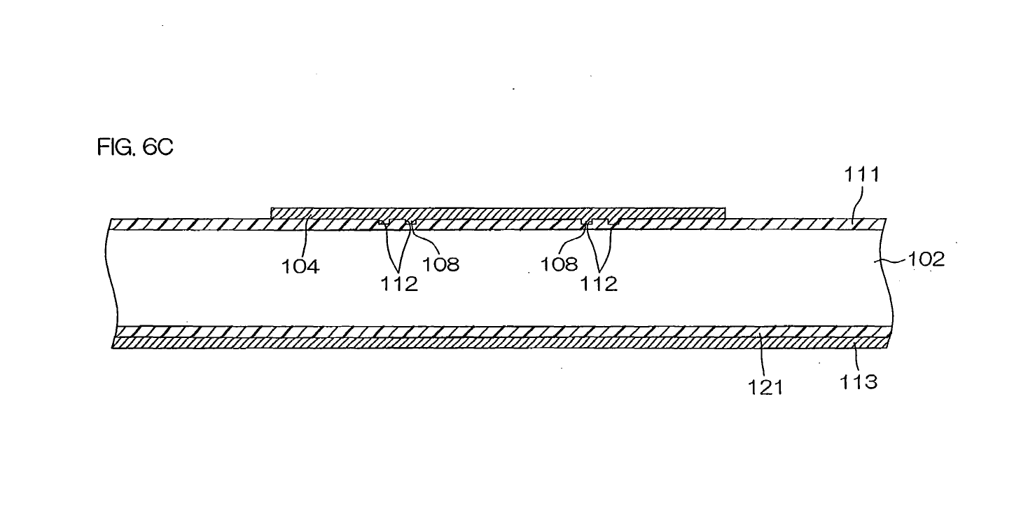

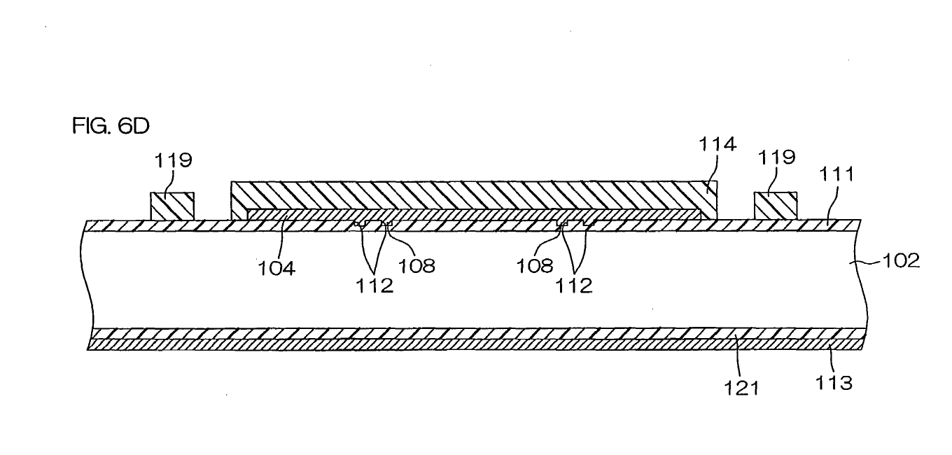

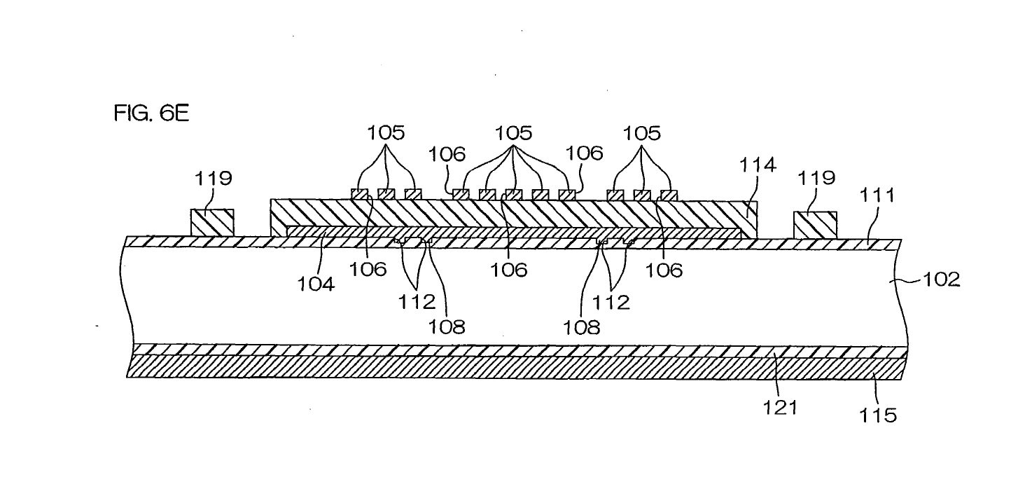

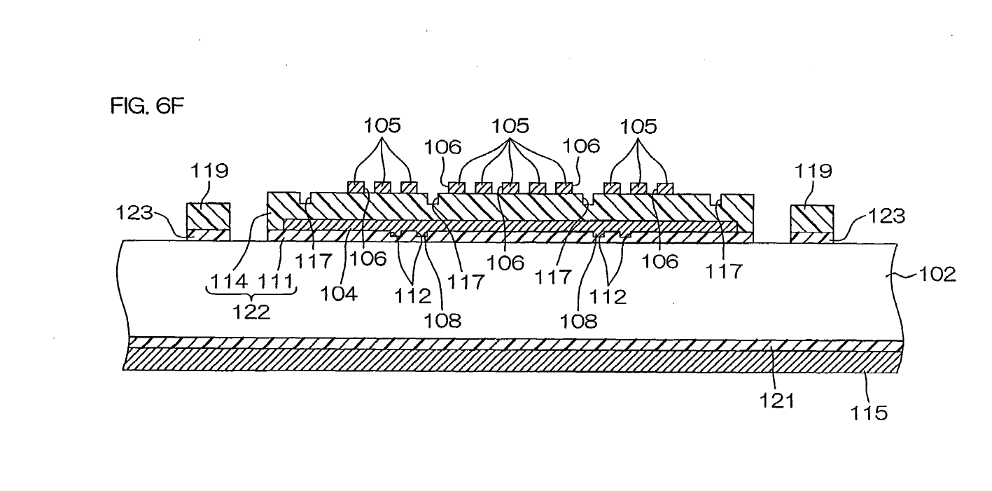

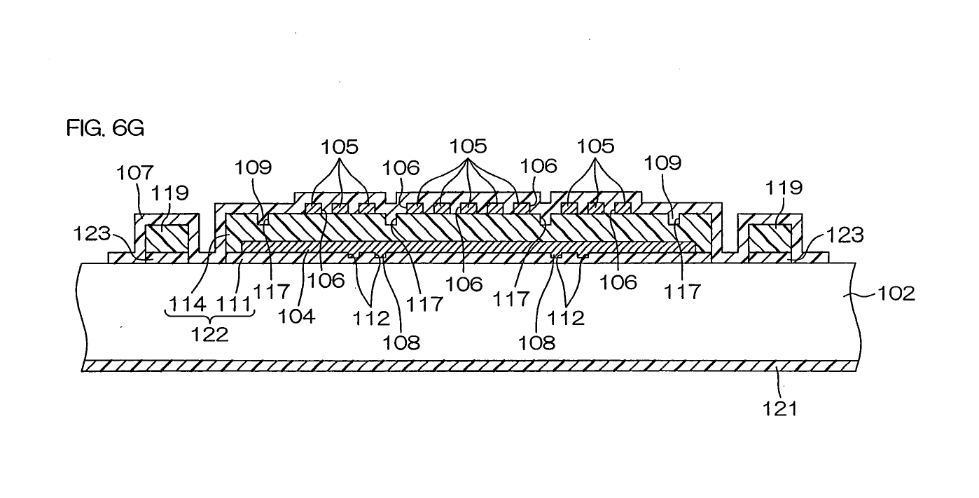

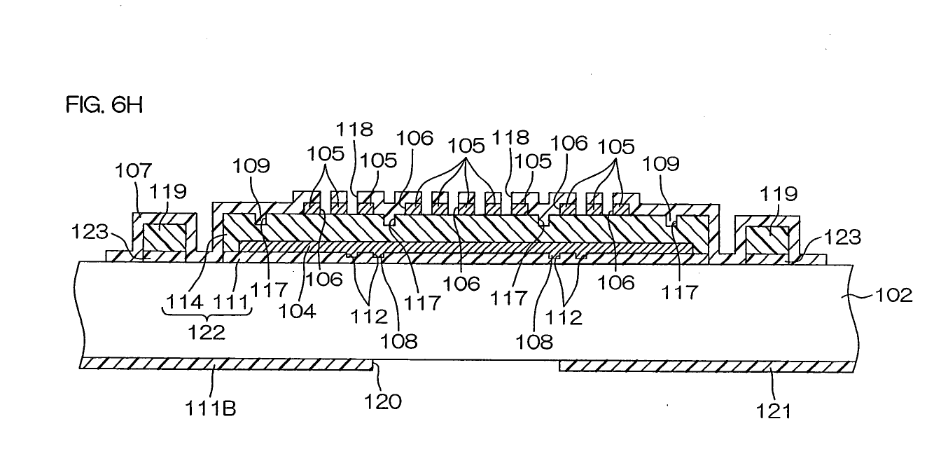

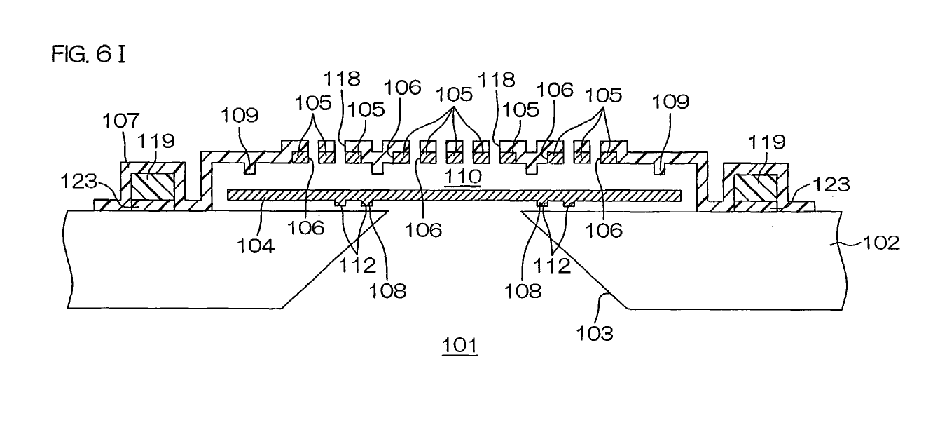

In the silicon microphone 101 shown in FIG. 6I, for example, the diaphragm 104 constituting one of the counter electrodes of the capacitor portion of the silicon microphone 101 is cantilever-supported by the first insulating film 123 and the second insulating film 119. Thus, there is an idea of increasing the vibrational amplitude of the diaphragm 104 and improving the sensitivity of the capacitor by supporting the diaphragm 104 by the untensioned cantilever-support. However, the untensioned diaphragm 104 is easily attracted to the back plate 105 by electrostatic force or the like.

According to the MEMS sensor of the aforementioned aspect, on the other hand, the main portion of the vibrating film is multiple-supported by the plurality of supporting portions, and the vibrating film is properly tensioned. Therefore, attraction of the vibrating film to the counter electrode can be suppressed. Consequently, contact between the counter electrode and the vibrating film can be suppressed.

In the aforementioned MEMS sensor, the resin material film is preferably made of a photosensitive organic material.

According to the structure, the resin material film is made of the photosensitive organic material. Therefore, the resin material film can be easily formed by patterning the photosensitive organic material into a prescribed pattern.

Embodiments of the present invention are now described in detail with reference to the attached drawings.

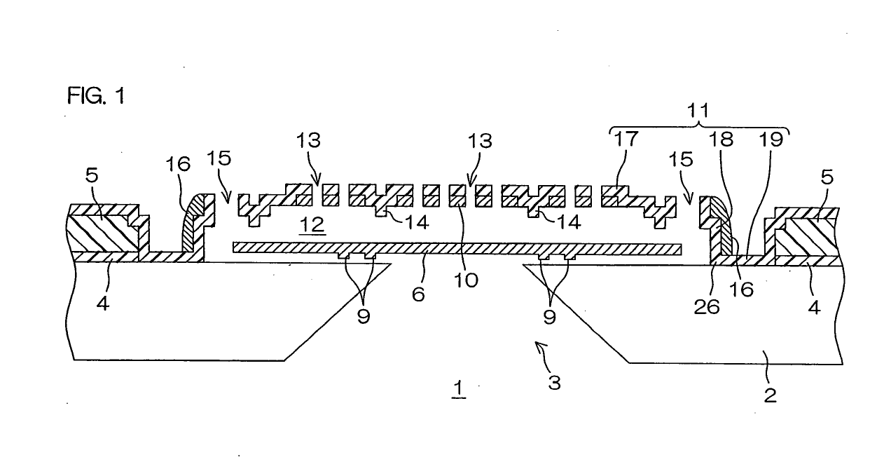

FIG. 1 is a schematic sectional view of a silicon microphone according to a first embodiment of the present invention.

A silicon microphone 1 is a device (an MEMS device) manufactured according to the MEMS technique. The silicon microphone 1 includes a silicon substrate 2. A sound hole 3 (a through-hole) passing through the silicon substrate 2 from a second side (from the side of the back surface) toward a first side (toward the side of the front surface) and having a trapezoidal sectional shape narrowed toward the first side (spreading toward the second side) is formed in a central portion of the silicon substrate 2.

A first insulating film 4 is laminated on the silicon substrate 2. The first insulating film 4 is made of silicon oxide, for example.

A second insulating film 5 is laminated on the first insulating film 4. The second insulating film 5 is made of PSG (Phospho Silicate Glass), for example.

The first insulating film 4 and the second insulating film 5 are partially removed from the sound hole 3 and a portion (hereinafter referred to as a “through-hole peripheral portion”) of a first surface of the silicon substrate 2 located around the sound hole 3. Thus, the through-hole peripheral portion is exposed from the first insulating film 4 and the second insulating film 5.

A diaphragm 6 is provided above the silicon substrate 2. The diaphragm 6 is made of polysilicon doped with an impurity to be conductive, for example. The diaphragm 6 is cantilever-supported by the first insulating film 4 and the second insulating film 5 on an unshown position.

The diaphragm 6 has a portion circular in plan view, and is arranged in a state opposed to the sound hole 3 and the through-hole peripheral portion while floating up from the through-hole peripheral portion. Thus, the cantilever-supported diaphragm 6 is rendered vibratile in a direction opposed to the first surface of the silicon substrate 2. A plurality of lower stoppers 9 in the form of protrusions are formed on the lower surface (the surface opposed to the through-hole peripheral portion) of the diaphragm 6 for preventing the diaphragm 6 and the through-hole peripheral portion from coming into close contact with each other.

A back plate 10 is provided above the diaphragm 6. The back plate 10 has a circular outer shape smaller in diameter than the circular portion of the diaphragm 6 in plan view, and is opposed to the diaphragm 6 with a gap. The back plate 10 is made of polysilicon doped with an impurity to be conductive, for example.

The outermost surface of the silicon microphone 1 is covered with a surface film 11. The surface film 11 is made of silicon nitride, for example, and covers the upper surfaces of the second insulating film 5 and the back plate 10.

The surface film 11 integrally has an opposed portion 17 opposed to the first surface of the silicon substrate 2 at an interval by covering the back plate 10, a step portion 19 formed on the first surface of the silicon substrate 2 on a side of the diaphragm 6, and a side portion 18 connecting the opposed portion 17 and the step portion 19 with each other and surrounding the side of the diaphragm 6 at an interval from the peripheral edge of the diaphragm 6. Thus, the surface film 11 is supported in a state having a hollow portion between the same and the first surface of the silicon substrate 2. Therefore, a space 12 partitioned by the surface film 11 (the opposed portion 17, the side portion 18 and the step portion 19) is formed on the silicon substrate 2, and the diaphragm 6 is arranged in the space 12 in a state not in contact with the silicon substrate 2 and the surface film 11.

A protective film 16 is formed on the side portion 18 of the surface film 11 in close contact with the overall region of the side surface thereof. The protective film 16 is made of a material, such as an inorganic such as titanium nitride (TiN), tantalum nitride (TaN) or tungsten nitride (WN) or an organic substance such as organic SOG (Spin On Glass) or polyimide, for example, having an etching selection ratio to the surface film 11. The thickness of the protective film 16 is preferably 100 to 500 nm. When the protective film 16 has a prescribed thickness, the overall region of the side surface of the side portion 18 of the surface film 11 and the surface of a portion (a step corner portion 26) of the side portion 18 intersecting with the step portion 19 are covered with the protective film 16.

A large number of small holes 13 continuously passing through the back plate 10 and the surface film 11 are formed in the back plate 10 and the surface film 11. The surface film 11 enters partial holes 13, and upper stoppers 14 in the form of protrusions protruding downward beyond the lower surface (the surface opposed to the diaphragm 6) of the back plate 10 are formed on the portions of the surface film 11 entering the holes 13. The upper stoppers 14 are so formed as to inhibit the diaphragm 6 from coming into contact with the back plate 10 when the diaphragm 6 vibrates.

A plurality of communication holes 15 are formed in the surface film 11 around the back plate 10 in a circularly aligned manner.

The diaphragm 6 and the back plate 10 constitute a capacitor having the diaphragm 6 and the back plate 10 as counter electrodes. A prescribed voltage is applied to the capacitor (between the diaphragm 6 and the back plate 10). When the diaphragm 6 vibrates by a sound pressure (a sound wave) in this state, the capacitance of the capacitor changes, and voltage fluctuation between the diaphragm 6 and the back plate 10 resulting from the change of the capacitance is extracted (output) as a sound signal.

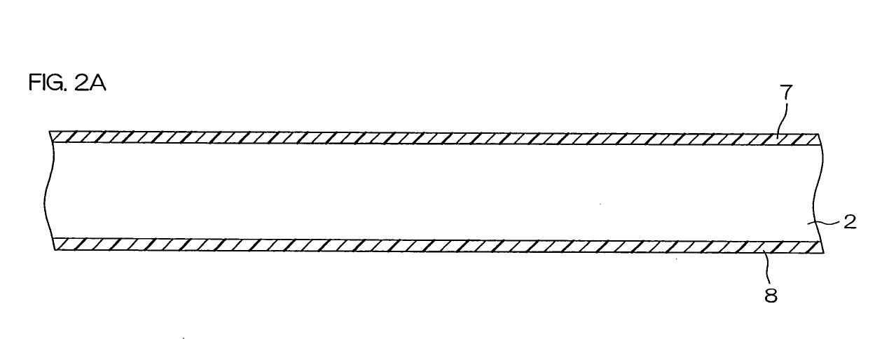

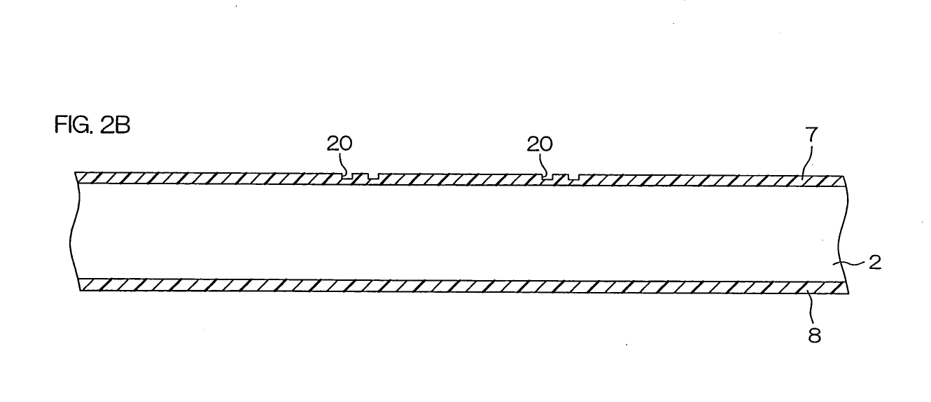

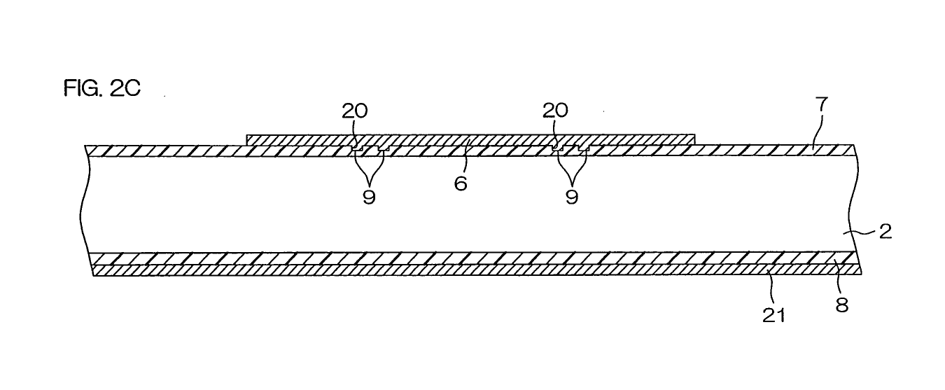

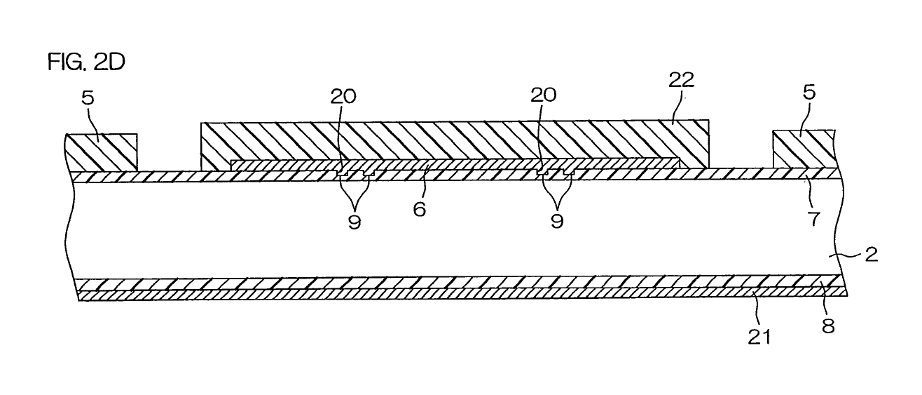

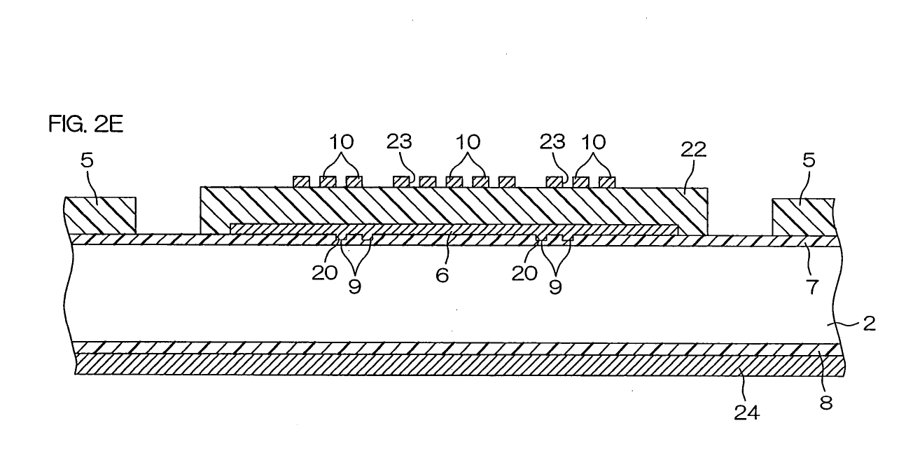

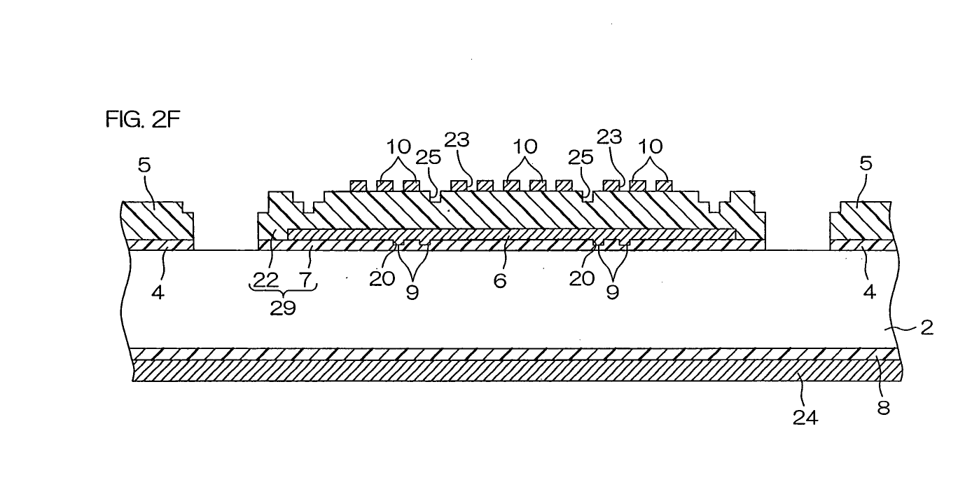

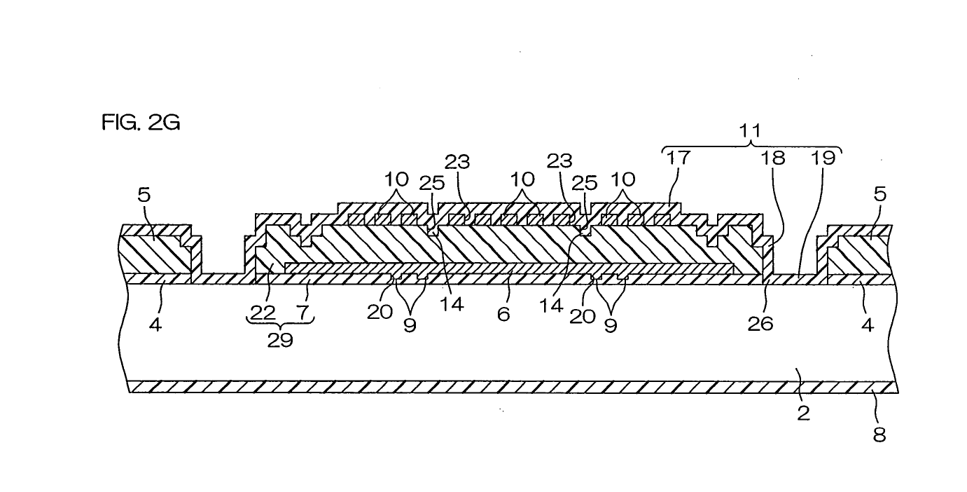

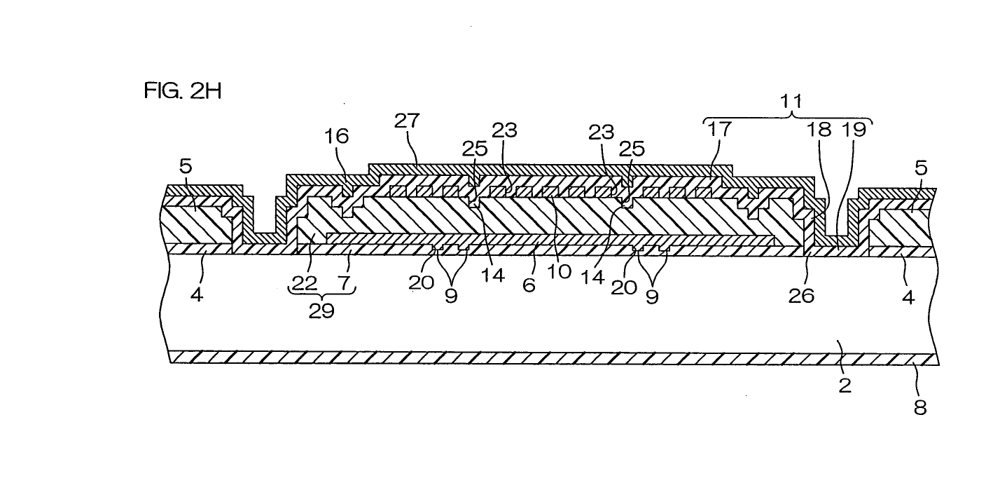

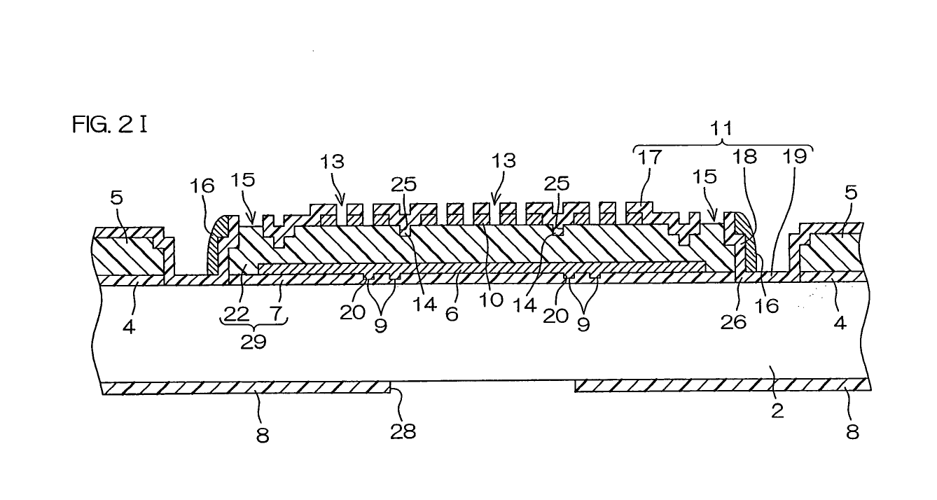

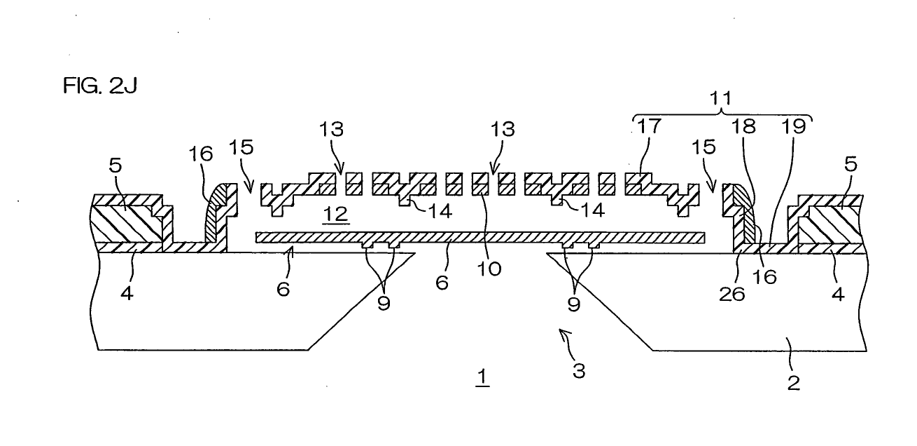

FIGS. 2A to 2J are schematic sectional views showing a method of manufacturing the silicon microphone 1 shown in FIG. 1 in step order.

In order to manufacture the silicon microphone 1, a thermal oxide film 7 and a thermal oxide film 8 are first formed on the first surface and a second surface of the silicon substrate 2 respectively by thermal oxidation, as shown in FIG. 2A.

Then, a plurality of recesses 20 are formed in the thermal oxide film 7 by etching the thermal oxide film 7 from the upper surface thereof in a prescribed pattern by well-known photolithography and etching, as shown in FIG. 2B.

Then, polysilicon is deposited by LPCVD (Low Pressure Chemical Vapor Deposition), to cover the overall regions of the surfaces of the thermal oxide films 7 and 8. The polysilicon covering the thermal oxide film 7 is doped with an impurity, and portions of the polysilicon other than prescribed portions including those entering the recesses 20 are thereafter removed. Thus, the diaphragm 6 having the plurality of lower stoppers 9 entering the recesses 20 thereby protruding toward the first surface of the silicon substrate 2 is formed, as shown in FIG. 2C. On the other hand, a polysilicon film 21 consisting of the deposited polysilicon is formed on the thermal oxide film 8, as shown in FIG. 2C.

Then, silicon oxide is deposited on the thermal oxide film 7 by PECVD (Plasma Enhanced Chemical Vapor Deposition), to cover the diaphragm 6. Unnecessary portions of the silicon oxide are removed by etching. Thus, a sacrificial oxide film 22 covering the diaphragm 6 and the second insulating film 5 surrounding the diaphragm 6 are formed, as shown in FIG. 2D.

Then, polysilicon is deposited on the first side and the second side of the silicon substrate 2 by LPCVD. The polysilicon deposited on the first side of the silicon substrate 2 is doped with an impurity, and thereafter patterned by well-known photolithography and etching. Thus, the back plate 10 having a large number of holes 23 is formed on the sacrificial oxide film 22 on the first side of the silicon substrate 2, as shown in FIG. 2E. On the second side of the silicon substrate 2, on the other hand, the deposited polysilicon and the polysilicon film 21 are integrated into a polysilicon film 24, as shown in FIG. 2E.

Then, the sacrificial oxide film 22 is etched through the holes 23 by well-known photolithography and etching, as shown in FIG. 2F. Thus, a plurality of recesses 25 are formed in prescribed portions of the sacrificial oxide film 22 opposed to the holes 23. Further, portions of the thermal oxide film 7 exposed from the sacrificial oxide film 22 and the second insulating film 5 are removed by well-known photolithography and etching, as shown in FIG. 2F. Thus, a sacrificial oxide film 29 is formed by the portion of the thermal oxide film 7 remaining between the sacrificial oxide film 22 and the silicon substrate 2 and the sacrificial oxide film 22. Further, the first insulating film 4 is formed by the portion of the thermal oxide film 7 remaining between the second insulating film 5 and the silicon substrate 2.

Then, silicon nitride is deposited on the first side of the silicon substrate 2 by PECVD to cover the overall regions of the surfaces of the sacrificial oxide film 29 and the second insulating film 5, as shown in FIG. 2G. Thus, the surface film 11 having the plurality of upper stoppers 14 entering the recesses 25 of the sacrificial oxide film 22 thereby protruding toward the first surface of the silicon substrate 2 is formed.

Then, a protective film material 27 is deposited on the first side of the silicon substrate 2 by sputtering or CVD to cover the overall region of the surface (the overall surface) of the surface film 11, as shown in FIG. 2H. The protective film material 27 is a material such as the aforementioned inorganic substance such as titanium nitride (TiN), tantalum nitride (TaN) or tungsten nitride (WN) or the organic substance such as organic SOG (Spin On Glass) or polyimide, for example, whose etching selection ratio to the sacrificial film 29 is greater than the etching selection ratio of the surface film 11 to the sacrificial oxide film 29. The etching selection ratio of the protective film material 27 to the sacrificial oxide film 29 denotes the ratio of the etching rate of the protective film material 27 to the etching rate of the sacrificial oxide film 29, and is expressed as follows:

Etching selection ratio=(etching rate of sacrificial oxide film 29/etching rate of protective material 27)

On the other hand, the etching selection ratio of the surface film 11 to the sacrificial film 29 is expressed as follows:

Etching selection ratio=(etching rate of sacrificial oxide film 29/etching rate of surface film 11)

Then, portions of the protective film material 27 located on the opposed portion 17 and the step portion 19 of the surface film 11 are removed by etching back the protective film material 27, a shown in FIG. 2I. Thus, the protective film material 27 selectively remains on the side portion 18 of the surface film 11 opposed to the side surface of the sacrificial oxide film 29, to form the protective film 16.

Then, the communication holes 15 passing through the surface film 11 and reaching the sacrificial oxide film 29 are formed by etching the surface film 11 by well-known photolithography and etching, as shown in FIG. 2I. Further, portions of the surface film 11 opposed to the holes 23 are etched, as shown in FIG. 2I. Thus, the holes 13 are formed to continuously pass through the surface film 11 and the back plate 10.

On the other hand, an opening 28 is formed in the thermal oxide film 8 by etching a portion of the thermal oxide film 8 opposed to the diaphragm 6 by well-known photolithography and etching, as shown in FIG. 2I.

Then, the silicon substrate 2 is dipped in a vessel filled up with an etching solution containing hydrofluoric acid, for example. Thus, the etching solution is supplied to the second surface of the silicon substrate 2 through the opening 28, to etch the silicon substrate 2 from the second side. Further, the etching solution is supplied to the sacrificial oxide film 29 through the communication holes 15 and the holes 13, to remove the sacrificial oxide film 29.

Thus, the sound hole 3 passing through the silicon substrate 2 from the second surface toward the first surface is formed in the silicon substrate 2, as shown in FIG. 2J. Further, the diaphragm 6 floats up from the first surface of the silicon substrate 2, and the space 12 of a small interval is formed between the diaphragm 6 and the back plate 10. The surface film 11 having covered the sacrificial oxide film 29 forms a hollow supporting film supported in a state having the hollow portion between the same and the first surface of the silicon substrate 2, due to the removal of the sacrificial oxide film 29.

Thereafter the silicon microphone 1 is obtained by dividing the silicon substrate 2 into the size of each device.

According to the aforementioned method, as hereinabove described, the protective film 16 is formed on the side portion 18 of the surface film 11 opposed to the side surface of the sacrificial oxide film 29 in advance of the etching of the sacrificial oxide film 29 (the sacrificial oxide film 22 and the thermal oxide film 7). The protective film 16 is made of the protective film material 27 whose etching selection ratio to the sacrificial oxide film 29 is greater than the etching selection ratio of the surface film 11 to the sacrificial oxide film 29. In other words, the relation can be expressed as follows:

(etching rate of sacrificial oxide film 29/etching rate of protective film 16 (protective film material 27)>(etching rate of sacrificial oxide film 29/etching rate of surface film 11)

Therefore, the protective film 16 having a smaller quantity of etching (a smaller quantity of erosion) by the etching solution (a solution containing hydrofluoric acid, for example) for removing the sacrificial oxide film 29 than the surface film 11 is formed on the side portion 18 of the surface film 11.

When the sacrificial oxide film 29 is etched, therefore, the quantity of erosion of the side portion 18 of the surface film 11 by the etching solution can be reduced. Consequently, damage of the surface film 11 induced by the etching can be suppressed.

On the side portion 18 of the surface film 11, the step corner portion 26 is particularly easily damaged by the etching due to the step coverage thereof. However, the surface of the step corner portion 26 can be reliably covered with the protective film 16, due to the prescribed thickness of the protective film 16. Consequently, damage of the step corner portion 26 can be effectively suppressed.

Damage of the surface film 11 induced by the etching may conceivably be suppressed by a technique of presuming the quantity of erosion of the surface film 11 by the etching and uniformly increasing the thickness of the surface film 11 on the basis of the presumed quantity of erosion, for example. In order to form the surface film 11 with a large thickness, however, the CVD treatment time (see FIG. 2G) for forming the surface film 11 and the patterning time (see FIG. 2I) for the surface film 11 must be increased. If the technique is employed while omitting formation of the protective film 16, therefore, the time for manufacturing the silicon microphone 1 is increased as a whole, and the production efficiency is reduced.

According to the aforementioned method, on the other hand, the protective film material 27 is first deposited on the overall surface of the surface film 11 by sputtering or CVD (see FIG. 2H), and the protective film 16 is formed by etching back the deposited protective film material 27 (see FIG. 2I). In other words, the protective film 16 is prepared by the simple technique of depositing the protective film material 27 by sputtering or the like and etching back the deposited protective film material 27. In the aforementioned manufacturing method employing the technique, therefore, increase in the manufacturing time can be suppressed. Consequently, damage of the surface film 11 induced by the etching can be suppressed without reducing the production efficiency for the silicon microphone 1.

The protective film material 27 is etched back before the surface film 11 is worked into the hollow supporting film by removing the sacrificial oxide film 29. In other words, the surface film 11 is in a state supported by the sacrificial oxide film 29 when the protective film material 27 is etched back. Therefore, the protective film material 27 covering the overall surface of the surface film 11 in this state can be etched back with excellent workability.

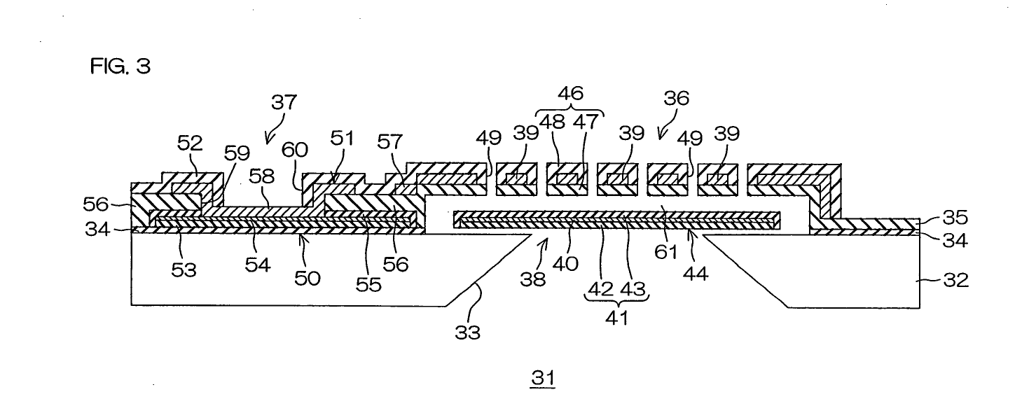

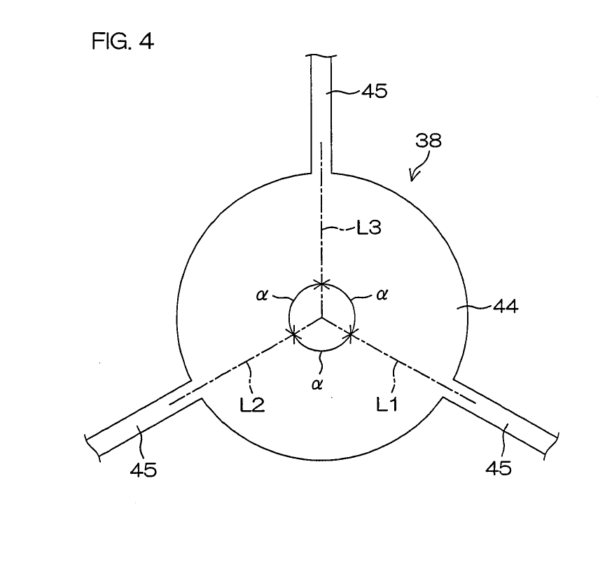

FIG. 3 is a schematic sectional view of a silicon microphone according to a second embodiment of the present invention. FIG. 4 is a schematic plan view of a diaphragm shown in FIG. 3.

A silicon microphone 31 includes a silicon substrate 32. A sound hole 33 having a trapezoidal sectional shape narrowed toward the side (a first side) of the upper surface (spreading toward the lower surface) is formed in the silicon substrate 32. A first insulating film 34 is laminated on the silicon substrate 32. The first insulating film 34 is made of silicon oxide, for example.

A second insulating film 35 is laminated on the first insulating film 34. The second insulating film 35 is made of silicon nitride, for example.

The first insulating film 34 and the second insulating film 35 are partially removed from the sound hole 33 and a portion (hereinafter referred to as a “through-hole peripheral portion”) of the upper surface of the silicon substrate 32 located around the sound hole 33. Thus, the through-hole peripheral portion is exposed from the first insulating film 34 and the second insulating film 35.

The silicon microphone 31 has a sensor portion 36 provided on the through-hole peripheral portion of the silicon substrate 32 and a pad portion 37 provided on a side of the sensor portion 36.

The sensor portion 36 includes a diaphragm 38 in the form of a thin film arranged above the upper surface (a first surface) of the silicon substrate 32 to be opposed thereto at an interval and a back plate 39 in the form of a mesh thin film opposed to the diaphragm 38 at an interval on the side of upper surface (the first side) of the silicon substrate 32.

The diaphragm 38 as a vibrating film has a metal electrode 40 in the form of a thin film and a diaphragm covering film 41 as a resin material film covering the metal electrode 40.

The metal electrode 40 is made of a metal abundant in ductility, for example. More specifically, the metal electrode 40 is made of aluminum (Al), titanium (Ti), titanium nitride (TiN), an aluminum-copper alloy (Al—Cu), copper (Cu), gold (Au), titanium tungsten (TiW), tungsten (W), tantalum (Ta), tantalum nitride (TaN) or the like. The thickness of the metal electrode 40 is 0.1 to 1 μm, for example, and preferably 0.3 to 0.5 μm.

The diaphragm covering film 41 is made of a photosensitive organic resin material, for example. More specifically, the diaphragm covering film 41 is made of polyimide resin, epoxy resin, acrylic resin or the like. The diaphragm covering film 41 has a lower covering film 42 covering the metal electrode 40 from below and an upper covering film 43 covering the metal electrode 40 from above. Thus, the diaphragm 38 has a three-layer structure in which the metal electrode 40 in the form of a thin film is vertically held by the upper covering film 43 and the lower covering film 42. The total thickness of the diaphragm 38 having the three-layer structure is 0.5 to 2 μm, for example, and preferably 0.7 to 1 μm.

The diaphragm 38 integrally has a main portion 44 storing the metal electrode 40 and three supporting portions 45.

The main portion 44 is circular in plan view, and arranged in a state opposed to the sound hole 33 and the through-hole peripheral portion while floating up from the through-hole peripheral portion.

The three supporting portions 45 extend from three positions of the peripheral edge of the main portion 44 in directions (sides) along the upper surface of the silicon substrate 32. The three supporting portions 45 are arranged on the three positions separated from one another by an angle α around the center of the main portion 44 respectively. In other words, the three supporting portions 45 are arranged so that a straight line L1 connecting one of each adjacent pair of supporting portions 45 with the center of the main portion 44 and a straight line L2 (or a straight line L3) connecting the other supporting portion 45 with the center of the main portion 44 form an angle of about 120°. The forward end portions of two of the three supporting portions 45 enter the space between the first insulating film 34 and the second insulating film 35 on unshown positions, to be supported by the first insulating film 34 and the second insulating film 35. On the other hand, the remaining supporting portion 45 is formed integrally with a lower wiring portion 50 (described later), and supported by the lower wiring portion 50 (described later). The main portion 44 is supported by the three supporting portions 45, whereby the diaphragm 38 is rendered vibratile in a direction opposed to the upper surface of the silicon substrate 32 in a state tensioned outward.

The back plate 39 as a counter electrode is made of a conductive material (aluminum, for example), and the thickness thereof is 0.3 to 1 μm, for example, and preferably 0.3 to 0.5 μm. The back plate 39 is covered with the back plate covering film 46.

The back plate covering film 46 is made of silicon nitride, for example, and has a lower covering film 47 formed integrally with the second insulating film 35 to cover the back plate 39 from below and an upper covering film 48 covering the back plate 39 from above. Small holes 49 are formed in positions of the back plate covering film 46 opposed to holes of the back plate 39, to pass through the back plate covering film 46 (to pass through the upper covering film 48 and the lower covering film 47) in the thickness direction.

The pad portion 37 includes the lower wiring portion 50, an upper wiring portion 51 and a passivation film 52.

The lower wiring portion 50 has a third insulating film 53, a lower wire 54 and a fourth insulating film 55.

The third insulating film 53 is made of a photosensitive organic resin material identical to the material for the lower covering film 42, and laminated on the first insulating film 34.

The lower wire 54 is made of a metal abundant in ductility identical to the material for the metal electrode 40, and formed on the third insulating film 53.

The fourth insulating film 55 is made of a photosensitive organic resin material identical to the material for the upper covering film 43, and laminated on the lower wire 54.

The third insulating film 53, the lower wire 54 and the fourth insulating film 55 are formed integrally with the lower covering film 42, the metal electrode 40 and the upper covering film 43 in one of the supporting portions 45 of the diaphragm 38. Thus, the lower wire 50 is formed integrally with one of the supporting portions 45 of the diaphragm 38, and supports the diaphragm 38.

The upper wiring portion 51 has a fifth insulating film 56, an upper wire 57 and a pad 58.

The fifth insulating film 56 is made of silicon nitride identical to the material for the lower covering film 47, and formed integrally with the lower covering film 47.

The upper wire 57 is made of aluminum identical to the material for the back plate 39, and connected to the back plate 39.

The pad 58 is made of aluminum identical to the material for the back plate 39 and the upper wire 57. An opening 59 for partially exposing the lower wire 54 is formed in the fifth insulating film 56 and the fourth insulating film 55. The pad 58 covers the lower wire 54 in the opening 59, and the peripheral edge portion thereof extends onto the fifth insulating film 56.

The passivation film 52 is made of silicon nitride identical to the material for the upper covering film 48. The passivation film 52 covers the fifth insulating film 56, the upper wire 57 and the peripheral edge portions of the pad 58, and has a pad opening 60 for exposing a central portion (a portion in contact with the lower wire 54) of the pad 58. The passivation film 52 is formed integrally with the upper covering film 48, and supports the upper covering film 48.

In the silicon microphone 31, the diaphragm 38 and the back plate 39 are opposed to each other through a gap 61 of a prescribed interval, and constitute a capacitor having the diaphragm 38 and the back plate 39 as counter electrodes. A prescribed voltage is applied to the capacitor (between the diaphragm 38 and the back plate 39). When the diaphragm 38 vibrates by a sound pressure (a sound wave) in this state, the capacitance of the capacitor changes, and voltage fluctuation between the diaphragm 38 and the back plate 39 resulting from the change of the capacitance is extracted (output) from the pad 58 as a sound signal.

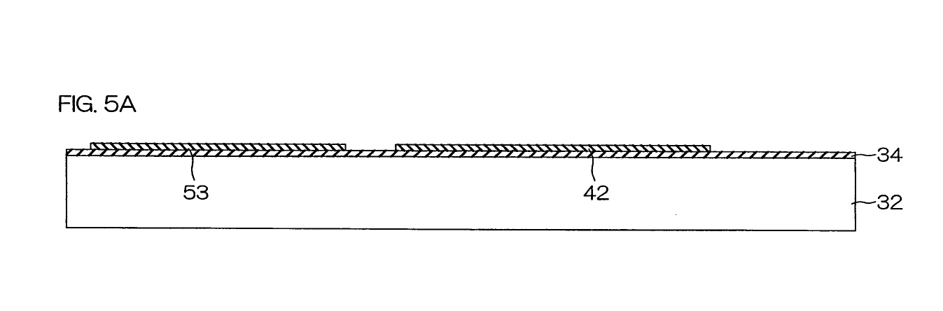

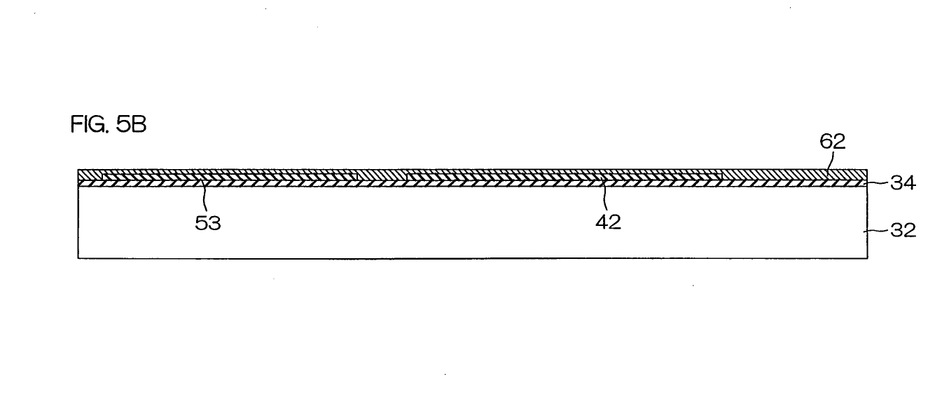

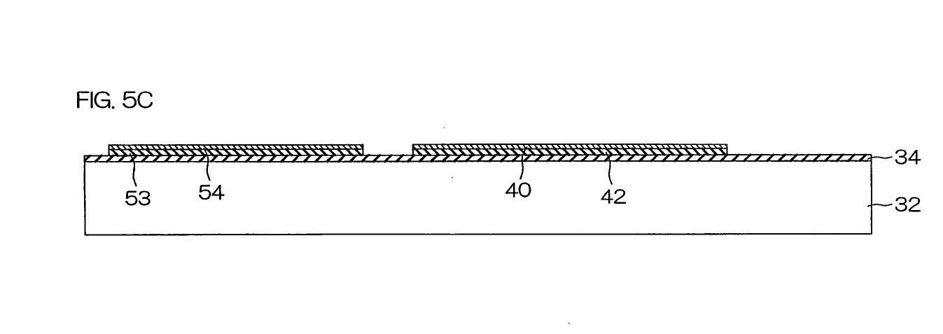

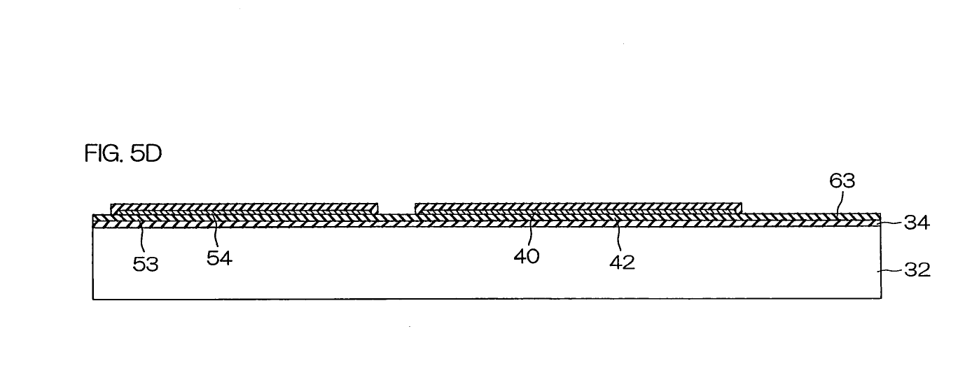

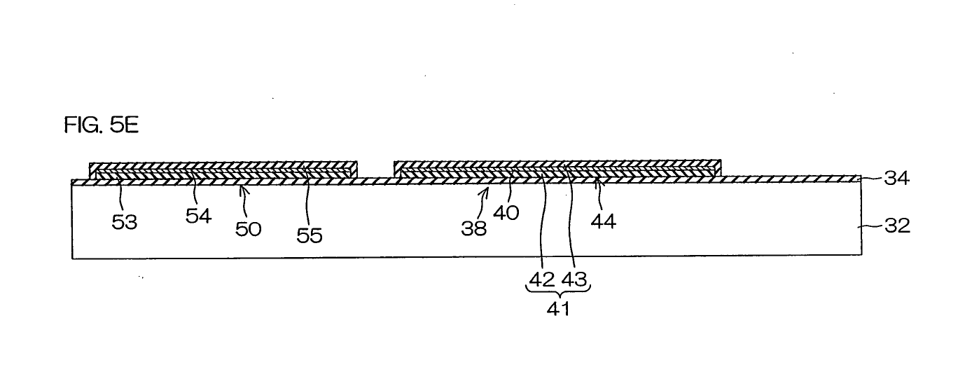

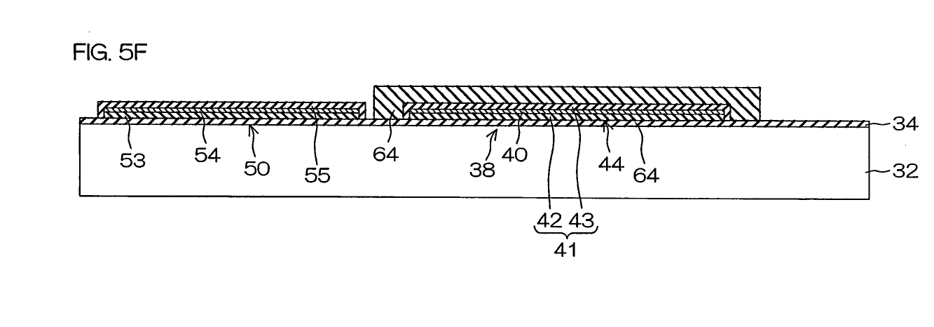

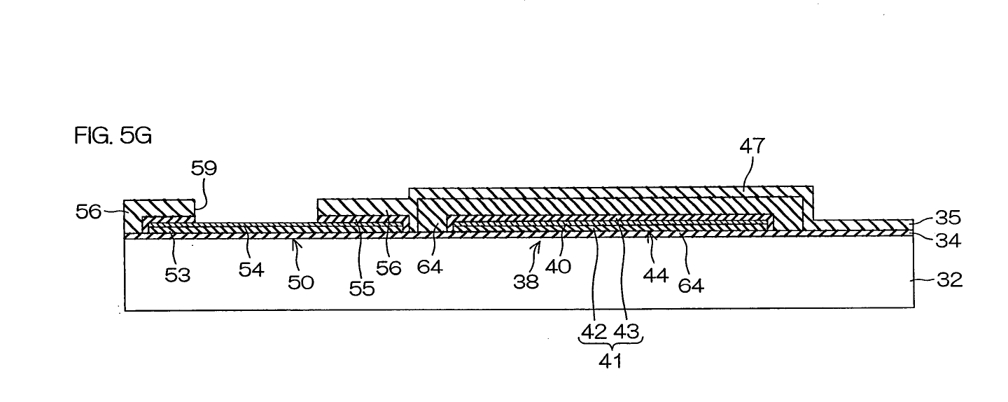

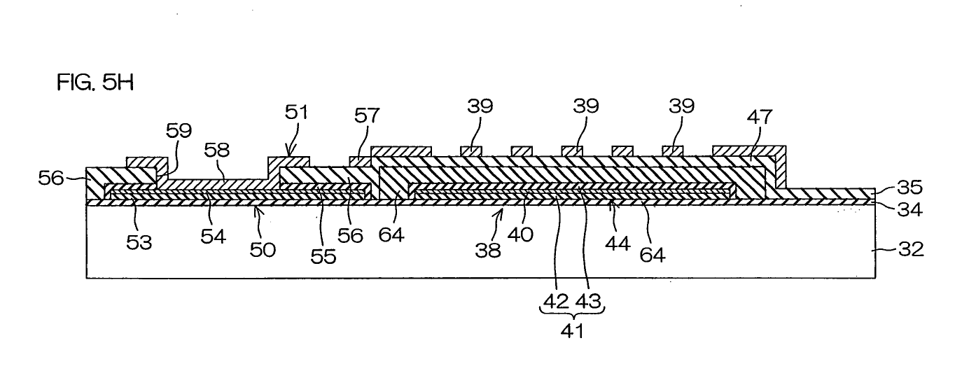

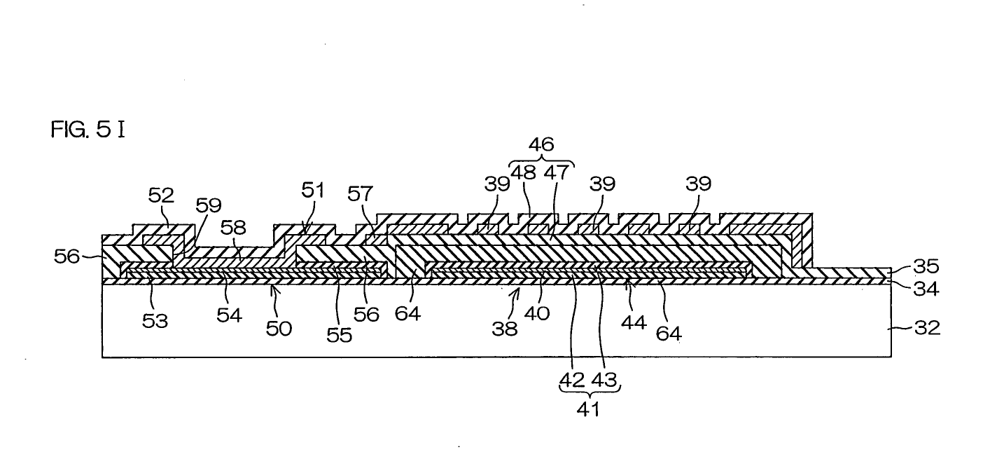

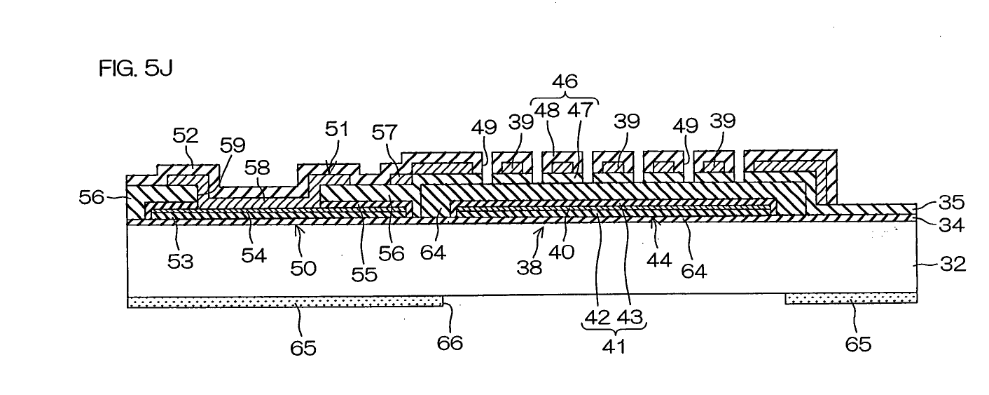

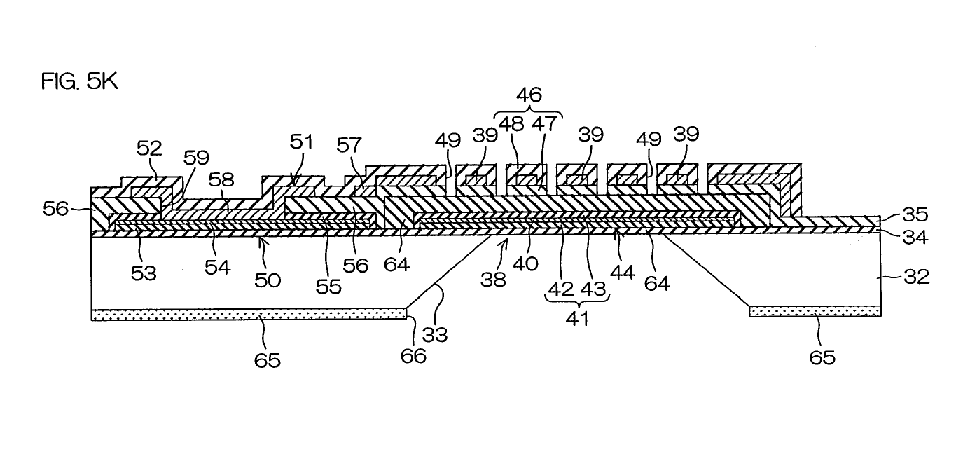

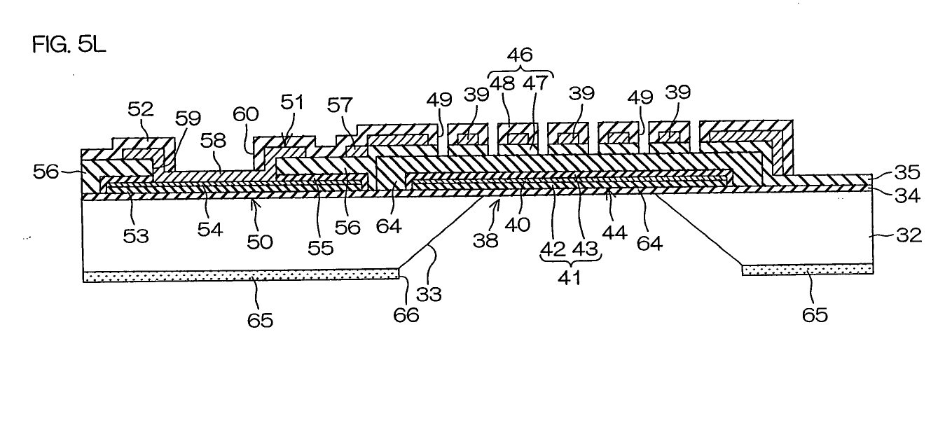

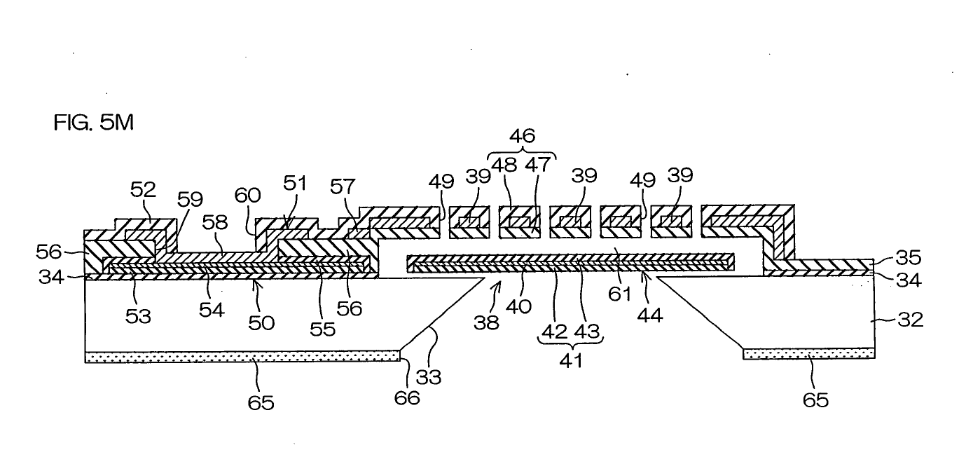

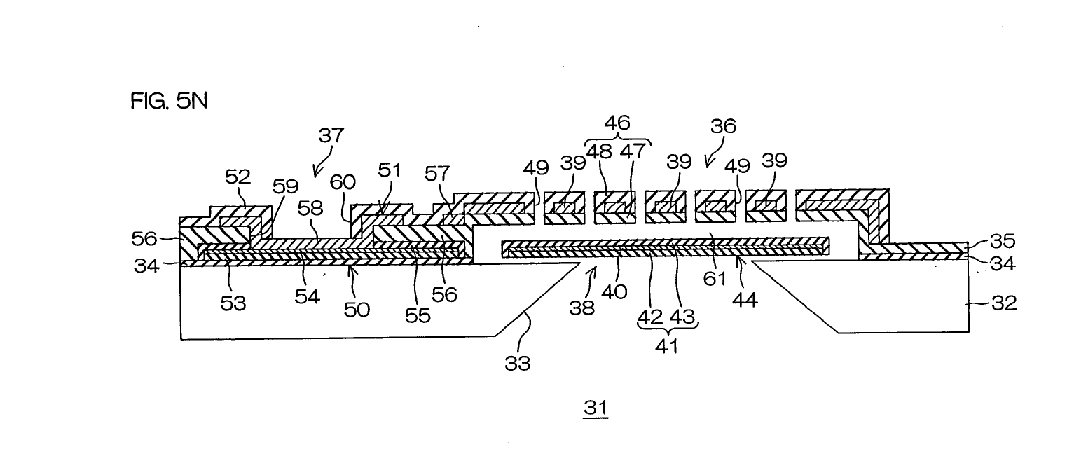

FIGS. 5A to 5N are schematic sectional views showing a method of manufacturing the silicon microphone 31 shown in FIG. 3 in step order.

In order to manufacture the silicon microphone 31 shown in FIG. 3, the first insulating film 34 is first laminated on the overall region of the upper surface of the silicon substrate 32 by thermal oxidation, as shown in FIG. 5A. Then, the material (the photosensitive organic resin material) for the lower covering film 42 and the third insulating film 53 is applied to the overall region of the upper surface of the first insulating film 34. Then, the applied material is patterned by well-known photolithography and etching. Thus, the lower covering film 42 and the third insulating film 53 are simultaneously formed on the first insulating film 34, as shown in FIG. 5A.

Then, a metallic material 62 for forming the metal electrode 40 and the lower wire 54 is deposited on the first insulating film 34 by sputtering, as shown in FIG. 5B. The metallic material 62 is deposited with a thickness for entirely covering the lower covering film 42 and the third insulating film 53.

Then, portions of the metallic material 62 other than those located on the lower covering film 42 and the third insulating film 53 are removed by well-known photolithography and etching, as shown in FIG. 5C. Thus, the metal electrode 40 is formed on the lower covering film 42, while the lower wire 54 is formed on the third insulating film 53.

Then, a photosensitive organic resin material 63 for forming the upper covering film 43 and the fourth insulating film 55 is applied onto the first insulating film 34 to entirely cover the metal electrode 40 and the lower wire 54, as shown in FIG. 5D.

Then, the upper covering film 43 covering the upper surface of the metal electrode 40 and sides of the lower covering film 42 and the metal electrode 40 is formed by selectively removing the photosensitive organic resin material 63 by well-known photolithography and etching, as shown in FIG. 5E. Thus, the diaphragm 38 having the metal electrode 48 covered with the diaphragm covering film 41 consisting of the lower covering film 42 and the upper covering film 43 is formed.

Further, the fourth insulating film 55 covering the upper surface of the lower wire 54 and sides of the third insulating film 53 and the lower wire 54 is formed by selectively removing the photosensitive organic resin material 63. Thus, the lower wiring portion 50 consisting of the third insulating film 53, the lower wire 54 and the fourth insulating film 55 is formed simultaneously with the diaphragm 38.

Then, silicon oxide is deposited on the overall upper region of the first insulating film 34 by CVD (Chemical Vapor Deposition), as shown in FIG. 5F. Then, a portion of the deposited silicon oxide covering the lower wiring portion 50 is selectively removed by well-known photolithography and etching. Thus, a portion of the silicon oxide covering the diaphragm 38 remains, and a sacrificial oxide film 64 is formed by the remaining portion and a portion of the first insulating film 34 located under the remaining portion and the diaphragm 38.

Then, silicon nitride is deposited on the overall region of the first insulating film 34 by CVD, as shown in FIG. 5G. Thus, the lower covering film 47 covering the sacrificial oxide film 64, the fifth insulating film 56 covering the lower wiring portion 50 and the second insulating film 35 are formed at the same time. Thereafter the fifth insulating film 56 and the fourth insulating film 55 are continuously etched into prescribed patterns by well-known photolithography and etching, as shown in FIG. 5G. Thus, the opening 59 is formed to partially expose the lower wire 54.

Then, the material (aluminum) for the back plate 39 and the pad 58 is deposited by sputtering, as shown in FIG. 5H. Then, the deposited aluminum is patterned by well-known photolithography and etching. Thus, the back plate 39 in the form of a mesh thin film, the upper wire 57 and the pad 58 are formed at the same time, as shown in FIG. 5H. The upper wiring portion 51 consisting of the fifth insulating film 56, the upper wire 57 and the pad 58 is formed in this manner.

Then, silicon nitride is deposited on the overall region of the first insulating film 34 by CVD to entirely cover the back plate 39, the upper wire 57 and the pad 58, as shown in FIG. 5I. Thus, the upper covering film 48 covering the upper surface and the side surface of the back plate 39 is formed, and the back plate covering film 46 consisting of the lower covering film 47 and the upper covering film 48 is formed.

Further, the passivation film 52 covering the upper wiring portion 51 is formed simultaneously with the back plate covering film 46.

Then, the back plate covering film 46 is patterned by well-known photolithography and etching, as shown in FIG. 5J. Thus, portions of the lower covering film 47 and the upper covering film 48 corresponding to the holes of the back plate 39 are removed, and the holes 49 are formed to pass through the back plate covering film 46. Further, photoresist 65 is applied to the lower surface of the silicon substrate 32, as shown in FIG. 5J. Then, an opening 66 exposing a region of the silicon substrate 32 for forming the sound hole 33 is formed by patterning the photoresist 65.

Then, the silicon substrate 32 is etched from the lower surface side by supplying an etching solution (hydrofluoric acid, for example) from the opening 66, as shown in FIG. 5K. Thus, the sound hole 33 is formed to pas through the silicon substrate 32 from the lower surface side toward the upper surface side.

Then, a portion of the passivation film 52 located on the pad 58 is removed by well-known photolithography and etching, as shown in FIG. 5L. Thus, the pad opening 60 is formed to expose the pad 58.

Then, an etching solution (hydrofluoric acid, for example) is supplied to the sacrificial oxide film 64 through the sound hole 33 and the holes 49 to remove the sacrificial oxide film 64 from both of the upper and lower sides of the silicon substrate 32, as shown in FIG. 5M. Thus, the diaphragm 38 floats up from the upper surface of the silicon substrate 32, and the gap 61 of a small interval is formed between the diaphragm 38 and the back plate 39. After the removal of the sacrificial oxide film 64, the photoresist 65 is removed.

Thus, the silicon microphone 31 having the sensor portion 36 and the pad portion 37 is obtained, as shown in FIG. 5N.

In the silicon microphone 31, as hereinabove described, the diaphragm 38 and the back plate 39 opposed to each other through the gap 61 constitute the capacitor having the diaphragm 38 and the back plate 39 as the counter electrodes. In the diaphragm 38 serving as one of the counter electrodes of the capacitor, the metal electrode 40 serving as a conductive portion is covered with the diaphragm covering film 41.

Even if the diaphragm 38 and the back plate 39 come into contact with each other, therefore, the diaphragm covering film 41 forming the surface of the diaphragm 38 inhibits the metal electrode 40 from coming into contact with the back plate 39. Consequently, a short circuit resulting from contact between the diaphragm 38 and the back plate 39 can be prevented. Further, the diaphragm 38 and/or the back plate 39 may not be provided with protrusions protruding in the opposed direction thereof, whereby complication of the manufacturing steps for the silicon microphone 31 can also be suppressed.

When the metal electrode 40 is covered with the diaphragm covering film 41, on the other hand, the diaphragm 38 more easily vibrates as compared with a diaphragm made of only a metallic material and formed to have the same thickness as the diaphragm 38. In the silicon microphone 31, for example, the diaphragm 38 is a thin-film electrode formed by covering the metal electrode 40 in the form of the thin film (having the thickness of 0.3 to 1 μm, for example) made of the metal abundant in ductility with the diaphragm covering film 41 consisting of a (photosensitive) organic resin material film. Therefore, the vibrational amplitude of the diaphragm 38 can be increased as compared with the diaphragm, made of only the metallic material, having the same thickness as the diaphragm 38. Consequently, the sensitivity of the silicon microphone 31 (the capacitor) can be improved. Therefore, a short circuit resulting from contact between the diaphragm 38 and the back plate 39 can be prevented while ensuring vibratility of the diaphragm 38.

Further, the metal electrode 40 is covered with the diaphragm covering film 41, whereby corrosion (deterioration) of the metal electrode 40 resulting from natural oxidation or the like can also be suppressed.

In the silicon microphone 101 shown in FIG. 6I, for example, the diaphragm 104 constituting one of the counter electrodes of the capacitor portion of the silicon microphone 101 is cantilever-supported by the first insulating film 123 and the second insulating film 119. Thus, there is an idea of increasing the vibrational amplitude of the diaphragm 104 and improving the sensitivity of the capacitor by supporting the diaphragm 104 by the untensioned cantilever-support. However, the untensioned diaphragm 104 is easily attracted to the back plate 105 by electrostatic force or the like.

In the silicon microphone 31, on the other hand, the main portion 44 of the diaphragm 38 is three-point-supported by the three supporting portions 45, and the diaphragm 38 is properly tensioned. Therefore, attraction of the diaphragm 38 to the back plate 39 can be suppressed. Consequently, contact between the diaphragm 38 and the back plate 39 can be suppressed.

Further, the diaphragm covering film 41 is made of the photosensitive organic resin material. Therefore, the diaphragm covering film 41 can be easily formed by carrying out the step (see FIG. 5A) of patterning the material for the lower covering film 42 and the step (see FIG. 5E) of patterning the photosensitive organic resin material 63 for forming the upper covering film 43 by well-known photolithography and etching.

While two embodiments of the present invention have been described, the present invention may be embodied in other ways.

For example, the protective film 16 protecting the surface film 11 may be formed on the opposed portion 17 and the step portion 19 of the surface film 11. However, the protective film 16 is preferably formed only on the side portion 18 of the surface film 11, as in the aforementioned embodiment. When the protective film 16 is formed only on the side portion 18 of the surface film 11, the distance between the protective film 16 and the back plate 10 can be increased. Also when the material for the protective film 16 is conductive, therefore, a short circuit between the back plate 10 and the protective film 16 can be suppressed.

The lower covering film 47 of the back plate covering film 46 may be omitted, for example. In other words, the lower surface of the back plate 39 may be exposed.

The diaphragm 38 may be cantilever-supported by supporting one supporting portion 45 on one point. The diaphragm 38 may be supported (two-point-supported) in a state where two supporting portions 45 are aligned with each other so that an angle formed by straight lines connecting the two supporting portions 45 and the center of the main portion 44 with one another is 180°, to be tensioned in the opposed direction through the main portion 44. Further, the diaphragm 38 may be supported on a plurality of points such as four, five or six points by providing four, five or six supporting portions 45.

While the silicon microphone is employed as an example of an MEMS device or an MEMS sensor, for example, the present invention is not restricted to the silicon microphone, but is applicable to an acceleration sensor for detecting the acceleration of a substance or a gyro sensor for detecting the angular speed of a substance, for example.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2008-239552 filed with the Japan Patent Office on Sep. 18, 2008 and Japanese Patent Application No. 2008-245863 filed with the Japan Patent Office on Sep. 25, 2008, the disclosures of which are incorporated herein by reference.

What is claimed is:

1. A method of etching a sacrificial layer, comprising the steps of:
forming a sacrificial layer having a protrusive shape on a base layer;
forming a covering film covering the sacrificial layer;
forming a protective film made of a material whose etching selection ratio to the sacrificial layer is greater than the etching selection ratio of the covering film to the sacrificial layer on a portion of the covering film opposed to the side surface of the sacrificial layer; and
etching the sacrificial layer after the formation of the protective film.

2. The method of etching a sacrificial layer according to claim 1, wherein
the step of forming the protective film includes the steps of depositing the material for the protective film on the overall surface of the covering film and leaving the material on a portion of the covering film opposed to the side surface of the sacrificial layer by etching back the deposited material.

3. A method of manufacturing an MEMS device, comprising the steps of:
forming a sacrificial layer having a protrusive shape on a surface of a substrate;
forming a covering film covering the sacrificial layer;
forming a protective film made of a material whose etching selection ratio to the sacrificial layer is greater than the etching selection ratio of the covering film to the sacrificial layer on a portion of the covering film opposed to the side surface of the sacrificial layer; and
working the covering film into a hollow supporting film supported in a state having a hollow portion between the same and the surface of the substrate by removing the sacrificial layer by etching thereby forming a space between the covering film and the substrate.

4. An MEMS device comprising:
a substrate;
a hollow supporting film, integrally having an opposed portion opposed to a surface of the substrate at an interval, a step portion formed on the surface of the substrate and a side portion connecting the opposed portion and the step portion with each other, supported in a state having a hollow portion between the same and the surface of the substrate; and
a protective film selectively formed on the side portion of the hollow supporting film.

5. An MEMS sensor comprising:
a substrate;
a vibrating film opposed to the substrate at an interval on a side of the substrate and vibratile in the opposed direction; and
a counter electrode, made of a conductive material, opposed to the vibrating film at an interval on a side of the vibrating film opposite to the substrate, wherein
the vibrating film includes a metal electrode and a resin material film covering the metal electrode.

6. The MEMS sensor according to claim 5, wherein
the vibrating film has a main portion on which the metal electrode is arranged and supporting portions extending from a plurality of positions of the peripheral edge of the main portion in directions along the surface of the substrate.

7. The MEMS sensor according to claim 5, wherein
the resin material film is made of a photosensitive organic material.
